(19) United States
(12) Patent Application Publication
(10) Pub. No.: US 2004/0080439 A1
(43) Pub. Date: Apr. 29, 2004

(54) System for and method for optimizing audio transfer resolution through the analog to digital conversion process

(76) Inventor: Lucas Van Der Mee, Los Angeles, CA (US)

Correspondence Address: Mark E. Ungerman, FULBRIGHT & JAWORSKI L.L.P., Market Square, 801 Pennsylvania Avenue, N.W., Washington, DC, 20004-2623, US

(21) Appl. No.: 10/279,909

(22) Filed: Oct. 25, 2002

(51) Int. Cl. H03M 1/12

(52) U.S. Cl. 341/139

(57) ABSTRACT

A system and method for optimizing audio transfer resolution including a digitally controlled analog gain control element receiving an incoming analog input, an analog to digital converter receiving an adjusted analog signal from the analog gain control element, a digital level measurement element receiving a digital signal from the analog to digital converter; and a processor receiving a level measurement control signal from the digital level measurement wherein the processor supplies a gain control signal to the analog gain control element.

### TECHNICAL FIELD

The present invention relates generally to the field of analog to digital conversion, and more particularly, to optimizing audio transfer resolution through the analog to digital conversion process.

### BACKGROUND OF THE INVENTION

Digital transmission and storage systems have a limited capacity of accurately transferring and storing the magnitude of digital signals. Digital signals are based upon a finite range of values including a maximum digital value. When an analog signal is converted to a digital signal, any analog signal that corresponds to a digital value higher than the maximum value cannot be accurately represented. In other words, Analog-To-Digital (A-D) converters clip input signals when the magnitude of the input signal exceeds the upper limit of the A-D converter. A level higher than the maximum allowable value is “clipped” to the maximum digital value, which is known as digital clipping or digital overload. These digital errors cause audible distortions. Methods to prevent digital overload include processing the signal before the A-D conversion with automatic gain devices. These devices modify the analog input level within a predetermined range to limit the maximum input level and reduce or eliminate digital clipping. Unfortunately, these devices also alter the overall characteristics of the audio signal relative to time. Another common method for reducing the probability of digital overload in digital recording or transmission is to operate at a reduced level to provide more capacity for signal peaks to pass without encountering the maximum allowable value. Operating at a reduced level means the incoming analog signal is reduced to eliminate or decrease subsequent clipping.

Digital signals also have a finite resolution of discrete values. As converter resolution increases, the steps used to quantize the analog waveform become “finer.” When incoming analog signals are reduced to eliminate clipping, the granularity or fineness of the steps to represent the analog waveform is also reduced. Reducing the input signal results in a reduction in the difference between the lowest level and highest level signal (the dynamic range). Low level signals that could have been accurately represented using the entire range of values may be lost in the conversion noise from the reduction in granularity.

One method to prevent overload when converting an audio signal to a digital signal and to prevent distortion is by ensuring the level of the analog signal is kept below the corresponding maximum allowable digital signal. This is typically accomplished by injecting the analog signal into a converter and checking for any overloads. If overloads occur, the level is manually reduced by the operator and a second pass is made. This process may take several iterations before the maximum analog signal level is identified and passed without creating a digital overload or distortion.

Another method to reduce or eliminate digital overloads is to input analog signals at a reduced level and then add gain in the digital domain after the A-D conversion has been completed with a technique called normalization. Normalization is where a digital signal is sampled to find the highest amplitude digital samples. Once the highest amplitude digital signals are identified, the gain of the digital signals would be increased to achieve the desired maximum level. Typically this level is a fraction of a decibel below the maximum allowable digital level. This process does not consider the incoming signal and will modify all resulting digital samples by the same calculated amount. Any noise will have the same increase in gain (amplitude multiplication), thereby raising the noise floor of the “normalized” signal as well. In addition, raising the digital level in this manner (multiplication) will not improve the ultimate resolution of the signal. This occurs because the entire dynamic range of the digital signal path was not used by the incoming analog signal.

U.S. Pat. No. 5,821,899, entitled “Automatic Clip Level Adjustment For Digital Processing,” purportedly automatically adjusts the analog input and output signal levels to optimize transfer resolutions through a digital processor. This system alters both the input and output gains of a digital process to theoretically maximize the resolution and reduce the probability of digital overloads. This system is designed to operate dynamically, changing the input gain and output gains together in a predetermined fashion, to maintain unity gain through the system so no perceived volume change is noted by maintaining an overall gain of unity in the two adjustments made.

### SUMMARY OF THE INVENTION

The present invention is directed to a system and method for optimizing audio transfer resolution including: a digitally controlled analog gain control element receiving an incoming analog input, an analog to digital converter receiving an adjusted analog signal from the analog gain control element, a digital level management element receiving a digital signal from the analog to digital converter; and a processor receiving a level measurement control signal from the digital level measurement wherein the processor supplies a gain control signal to the analog gain control element.

The foregoing has outlined rather broadly the features and technical advantages of the present invention in order that the detailed description of the invention that follows may be better understood. Additional features and advantages of the invention are described hereinafter and form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions does not depart from the spirit and scope of the invention as set forth in the claims. The novel features that are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

FIG. 1 is a waveform illustrating an example of an analog input signal received by the system of FIG. 3;

FIG. 2 is a waveform illustrating an example of the digitized audio signal values of the analog signal resulting from the A-D conversion of the waveform of FIG. 1 in the system of FIG. 3;

FIG. 3 is a simplified block diagram of an analog to digital processing system;

FIG. 4 illustrates the dynamic range and resolution results from a digital normalization process;

FIG. 5 illustrates the use of the dynamic range resulting from one embodiment of the present invention; and

FIG. 6 is a flow chart of the operation of one embodiment of FIG. 3.

### DETAILED DESCRIPTION OF THE INVENTION

One primary objective of the present invention is to provide a circuit configuration that employs automatic adjustment of an analog gain stage. This automatic adjustment is based upon an analysis, of a digital representation of the analog gain amplitude. The dependency of the automatic adjustment of the analog stage on the digital representation may be used to optimize the analog to digital transfer through the analog and digital signal paths.

An embodiment of the present invention may also automatically optimize analog to digital transfer of an audio signal based upon an analyzed digital representation of the analog signal and a predetermined set of dynamic range parameters applied to the signal in the analog domain.

Another objective of this invention is to maintain an analog signal that presents a consistent level range to an analog to digital conversion stage based upon a set of parameters.

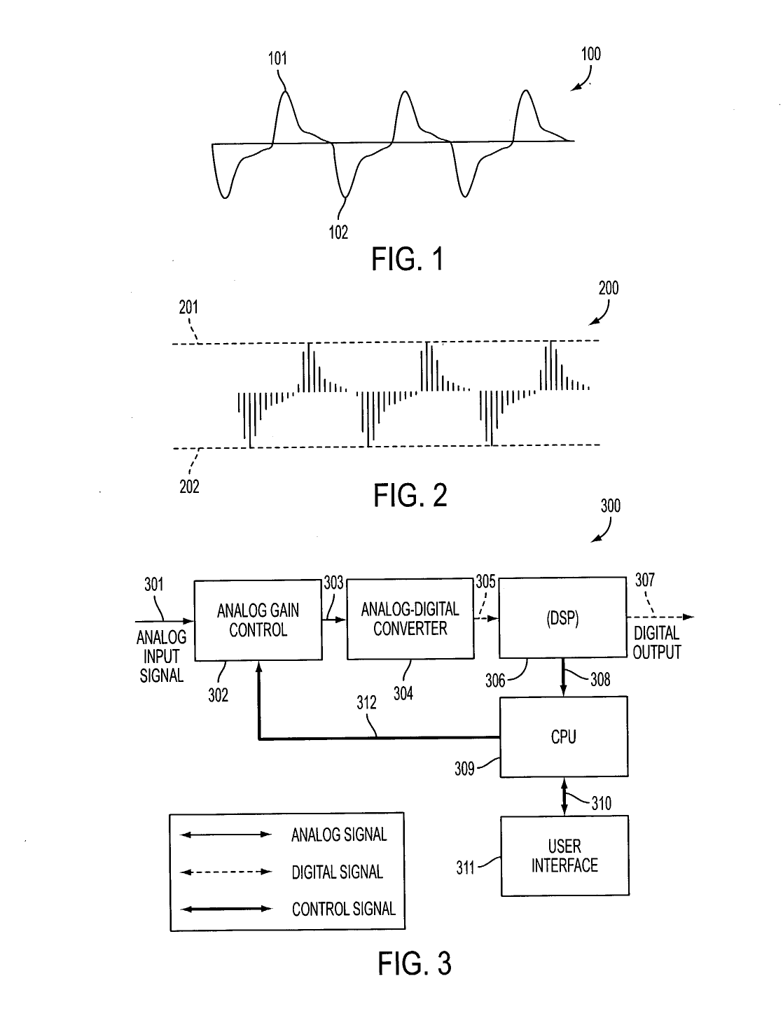

FIG. 1 is a waveform illustrating an example of an analog input signal 100 with maximum positive 101 and negative 102 amplitudes. This waveform may be applied to an analog to digital converter resulting in an output of a string of digits that represents the waveform in the digital domain.

FIG. 2 is a waveform illustrating an example of the digitized audio signal values 200 of the analog signal resulting from the A-D conversion of the waveform of FIG. 1. The digital measurement typically consists of signed integers with a finite maximum value. The maximum positive 201 and maximum negative 202 values are shown that correspond to the maximum positive 101 and negative 102 values of the analog waveform of FIG. 1.

FIG. 3 is a simplified block diagram of one embodiment of an analog to digital processing system 300 of the present invention. An analog input signal 301 is applied to the input of a gain element such as analog gain control 302. Analog gain control 302 is variable and computer controlled by Central Processing Unit (CPU) 309 through control line 312. In its simplest form analog gain control 302 applies a linear multiplier to analog input signal 301 to increase or decrease the amplitude by a fixed amount. Note that many other adjustments are possible and within the present invention. The resulting gain adjusted analog signal at 303 is applied to analog to digital converter 304 where the signal is changed from an analog signal to a digital representation of the analog signal. A digital representation of the signal is available at 305 and applied to a digital level measurement device such as Digital Signal Processor (DSP) 306. Note that other forms of digital level measurement could be substituted in place of dedicated DSP. Measurement of the amplitude of the digital signal is made by DSP 306 and the digital signal is available at digital output 307. Digital output 307 may be sent to a digital transmitter or other circuits for further manipulation.

A level measurement control signal is available at 308 and is sent to CPU 309. A user using user interface 311 may supply the desired control parameters through bi-directional control interface 310. Note that CPU 309 may be programmed to automatically apply predefined control parameters. CPU 309 calculates the correct gain control parameters using level measurement control signals applied at 308 and user interface signals at 310. These signals are available from DSP 306 and user interface 311. The correct parameters are sent from CPU 309 to analog gain control 302 by gain control signal path 312.

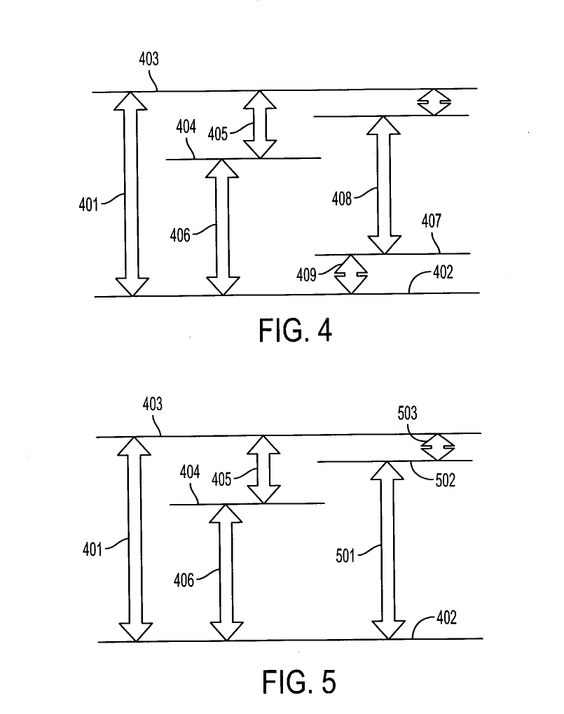

FIG. 4 illustrates the dynamic range and resolution resulting from a digital normalization process. FIG. 4 also shows the effect of the normalization scheme on the dynamic range and noise floor. The digital representation of the signal includes a dynamic range 401. Dynamic range 401 is the difference between digital minimum level 402 and digital maximum level 403. An input signal includes an input maximum level 404 indicating that the input signal is not using the total available dynamic range 401, with unused dynamic range 405 remaining. Adding gain 409 to input signal 406 in the digital domain results in a new noise floor 407 and no change to the input signal's dynamic range 408.

FIG. 5 illustrates the use of the dynamic range resulting from one embodiment of the present invention. Dynamic range 401, maximum level 403 and minimum level 402 remain unchanged from FIG. 4. Input signal 406 is applied to the system of FIG. 3 and converted to digital. DSP 306 (FIG. 3) measures the difference between the maximum level 403 and input maximum level of 404 of input signal 406. This measurement indicates the amount of unused gain 405. This measurement is used to calculate the desired gain by CPU 309 (FIG. 3) that is sent via gain control path 312 to analog gain control 302. The desired gain may also be dependent upon the value received from user interface 311. This can be any level below the maximum input level 403. The resulting signal 501 uses more of dynamic range 401 of the system. A maximum input level is now 502 leaving much less unused dynamic range 503.

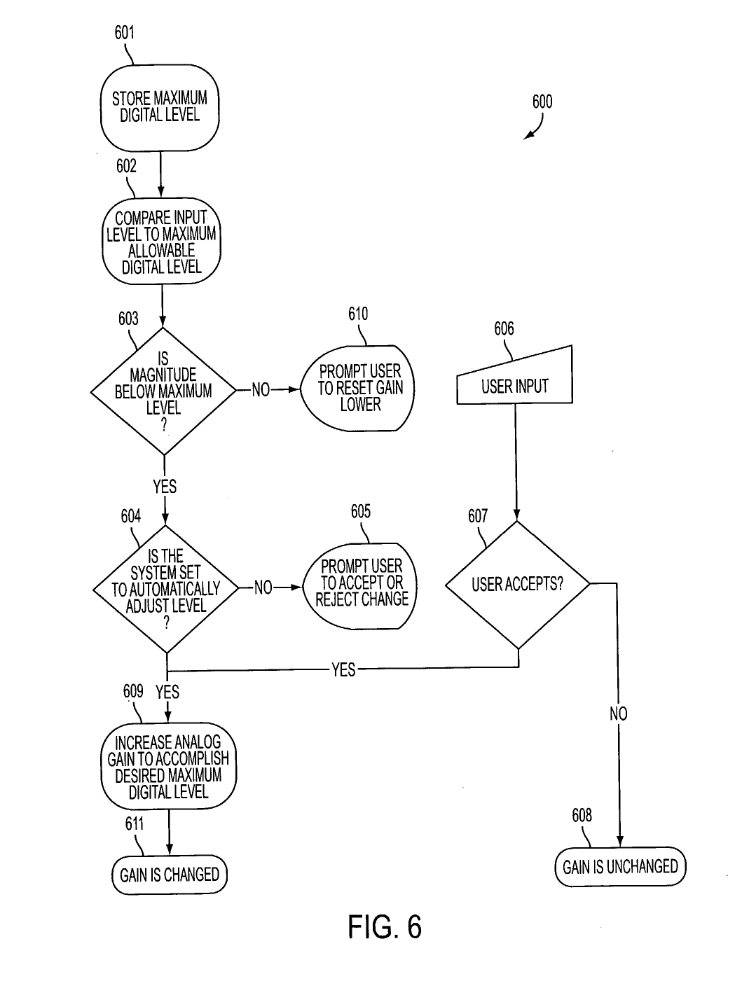

FIG. 6 represents a flow chart 600 of the operation of one embodiment of the present invention. Before an input signal is applied 406 (FIG. 4), maximum digital level (also called maximum level) 403 is stored in step 601. This maximum digital level 403 allowed by CPU 309 is compared to input level 406 in step 602. In step 603, if input level 406 is less than maximum digital level 403 step 610 prompts the user to reset gain lower.

In step 603, if input maximum 404 is below maximum level 403 and the system is set to automatically adjust the gain in step 604, CPU 309 will increase the analog gain using the analog gain control 302 in step 609. The gain is then changed in step 611. If the system is not set to automatically adjust the gain, the user will be prompted in step 605, through user interface 311, to accept or reject the change in step 605. Upon receipt of user input in step 606, the user will either accept the gain change or reject the change in step 607. If the gain change is rejected by the user in step 607, the gain will not be changed as shown in step 608. If the system is set to automatically adjust the gain in step 604, then the gain will be increased in step 609. If the input is at the maximum level 403 the invention will prompt the user to set the analog gain lower in step 610.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention defined by the appended claims.

The drawings constitute a part of this specification and include exemplary embodiments to the invention, that may be embodied in various forms. It is to be understood that in some instances various aspects of the invention may be shown exaggerated or enlarged to facilitate an understanding of the invention.

What is claimed is:

1. A system for optimizing audio transfer resolution comprising:
a digitally controlled analog gain control element receiving an incoming analog input;
an analog to digital converter receiving an adjusted analog signal from said analog gain control element;
a digital level measurement element receiving a digital signal from said analog to digital converter; and
a processor receiving a level measurement control signal from said digital level measurement wherein said processor supplies a gain control signal to said analog gain control element.

2. The system of claim 1 wherein said digital level measurement element is a digital signal processor.

3. The system of claim 1 further including:
a user interface electrically connected to said processor wherein said CPU receives an adjustment parameter from said user interface.

4. A method of optimizing audio transfer resolution through an analog to digital conversion comprising the steps of:
receiving an incoming analog input signal;
modifying said incoming analog input signal to create a gain adjusted analog signal;
converting said gain adjusted analog signal from analog to digital to provide a digital signal;
determining an amplitude of said digital signal;
determining a gain control parameter from said amplitude; and
adjusting said step of modifying based on said gain control parameter.

5. The method of claim 4 wherein said step of modifying includes adjusting an amplitude of said incoming analog input signal.

6. The method of claim 4 wherein said step of determining an amplitude of said digital signal includes measuring said amplitude.

7. The method of claim 4 further including a step of:
supplying a recommended gain control parameter to a user;
receiving an adjustment factor from said user; and
modifying said gain control parameter with said adjustment factor.

8. A method of optimizing audio transfer resolution through an analog to digital conversion comprising:
means for receiving an analog input signal;
means for controlling a gain of said analog input signal to produce a gain adjusted analog signal;
means for converting said gain adjusted analog signal to a gain adjusted digital signal;
means for determining an amplitude of said gain adjusted digital signal;
means for determining unused dynamic range;
means for adjusting said means for controlling to affect said unused dynamic range; and
means for adjusting said means for controlling said gain.

9. The method of claim 8 further including:
means for including a user supplied adjustment in said means for controlling.

10. A machine for optimizing audio transfer resolution through the analog to digital conversion process comprising:
an analog variable gain element for controlling the gain of an analog input signal;
an analog to digital converter for converting said analog input signal to a digital signal;
means of determining a maximum level of successive samples of said digital signal; and
means for adjusting said analog variable gain element.

11. The machine as claimed in claim 10 wherein the input gain control can be changed based upon a defined set of digital level characteristics.

12. The machine of claim 10 wherein the input gain control is set to a predetermined level after a user defined time period.

13. The machine of claim 10 that can be set to a predetermined level after a plurality of successive digital sample magnitudes exceed a user defined level.

14. The machine of claim 10 that will reset the analog gain to a preset level if the input magnitude remains below a user-defined threshold level.

15. The machine of claim 10 that will reset the analog gain to a preset level after a user-defined period of time.

16. The machine of claim 10 further including:
means for including user adjustment to said step of adjusting said analog variable gain element.
